(19) United States
(12) Patent Application Publication
(10) Pub. No.: US 2022/0223375 A1
(43) Pub. Date: Jul. 14, 2022

(54) ANTENNA AND PLASMA PROCESSING APPARATUS

(71) Applicant: Tokyo Electron Limited, Tokyo (JP)

(72) Inventors: Hitoshi KATO, Iwate (JP); Hiroyuki KIKUCHI, Iwate (JP)

(21) Appl. No.: 17/570,470

(22) Filed: Jan. 7, 2022

(30) Foreign Application Priority Data
Jan. 14, 2021 (JP) 2021-004432

(51) Int. Cl. H01J 37/32; C23C 16/40; C23C 16/505

(52) U.S. Cl. CPC H01J 37/3211; H01J 2237/332; C23C 16/505; C23C 16/401

(57) ABSTRACT

An antenna for inductively-coupled plasma is provided. The antenna is configured to be disposed on a predetermined process chamber. The antenna is configured to adjust an oxidizing amount or a nitriding amount of a substrate process in the process chamber by changing a shape thereof. The antenna includes an antenna member disposed on the process chamber. The antenna member has a position where an oxidizing amount or a nitriding amount becomes a predetermined value at each measurement point of the antenna member. The antenna member has a shape formed based on the position of the antenna member obtained at each measurement point.

### CROSS-REFERENCE TO RELATED APPLICATION

The present application is based on and claims priority to Japanese Priority Application No. 2021-004432 filed on Jan. 14, 2021, the entire contents of which are hereby incorporated herein by reference.

### BACKGROUND OF THE INVENTION

### 1. Field of the Invention

The present disclosure relates to an antenna and a plasma processing apparatus.

### 2. Description of the Related Art

Japanese Laid-Open Patent Application Publication No. 2018-41685 discloses an antenna including a plurality of antenna members extending along a predetermined track-like shape and having longitudinal coupling positions opposite to each other in a short-side direction so as to form a predetermined track-like shape having a longitudinal direction and a short-side direction. The antenna includes a deformable and electrically conductive coupling member connecting the ends of the adjacent plurality of antenna members, and at least two vertical moving mechanisms individually coupled to at least two of the plurality of antenna members and capable of raising and lowering at least two of the plurality of antenna members so as to change the bending angle of the coupling member as a fulcrum.

### SUMMARY OF THE INVENTION

The present disclosure provides an antenna that is shaped in accordance with an oxidizing amount or a nitriding amount in a substrate process.

According to one embodiment of the present disclosure, there is provided an antenna for inductively-coupled plasma. The antenna is configured to be disposed on a predetermined process chamber. The antenna is configured to adjust an oxidizing amount or a nitriding amount of a substrate process in the process chamber by changing a shape thereof. The antenna includes an antenna member disposed on the process chamber. The antenna member has a position where an oxidizing amount or a nitriding amount becomes a predetermined value at each measurement point of the antenna member. The antenna member has a shape formed based on the position of the antenna member obtained at each measurement point.

### BRIEF DESCRIPTION OF THE DRAWINGS

FIG. 1 is a vertical schematic cross-sectional view illustrating a plasma processing apparatus according to an embodiment of the present disclosure;

FIG. 2 is a schematic plan view illustrating a configuration of a plasma processing apparatus according to an embodiment of the present disclosure;

FIG. 3 is a cross-sectional view along a concentric circle of a susceptor of a plasma processing apparatus according to an embodiment of the present disclosure;

FIG. 4 is an example of a longitudinal sectional view of a plasma generator of a plasma processing apparatus according to an embodiment of the present disclosure;

FIG. 5 is an exploded perspective view of an example of a plasma generator of a plasma processing apparatus according to an embodiment of the present disclosure;

FIG. 6 is a perspective view of an example of a housing disposed in a plasma generator of a plasma processing apparatus according to an embodiment of the present disclosure;

FIG. 7 is a vertical cross-sectional view of a plasma processing apparatus cut through a vacuum chamber along a rotational direction of a susceptor according to an embodiment of the present disclosure;

FIG. 8 is a perspective view illustrating an enlarged view of a gas nozzle for plasma processing disposed in a plasma processing region of a plasma processing apparatus according to an embodiment of the present disclosure;

FIG. 9 is a plan view of an example of a plasma generator of a plasma processing apparatus according to an embodiment of the present disclosure;

FIG. 10 is a perspective view illustrating a part of a Faraday shield disposed in a plasma generator of a plasma processing apparatus according to an embodiment of the present disclosure;

FIG. 11 is a perspective view of an antenna device and a plasma generator according to embodiments of the present disclosure;

FIG. 12 is a side view of an antenna device and a plasma generator according to an embodiment of the present disclosure;

FIG. 13 is a side view of an antenna according to an embodiment of the present disclosure;

FIGS. 14A to 14C are diagrams for explaining a determination of a shape of an antenna according to the present disclosure;

FIGS. 15A and 15B show a table calculating an antenna height at which the oxidation power becomes 1, and a diagram showing a plot of an antenna shape, respectively;

FIGS. 16A to 16C are diagrams illustrating an example of a method of configuring an antenna according to the present embodiment;

FIG. 17 is a diagram illustrating a specific shape of the optimization of FIG. 16;

FIGS. 18A to 18D are diagrams showing a result of measuring an oxidizing force using an antenna; and

FIG. 19 is a diagram showing, in more detail, film thicknesses of a silicon oxide film deposited using an antenna.

### DETAILED DESCRIPTION OF THE PREFERRED EMBODIMENTS

Hereinafter, embodiments for carrying out the present invention will be described with reference to the drawings.

[Configuration of Plasma Processing Apparatus]

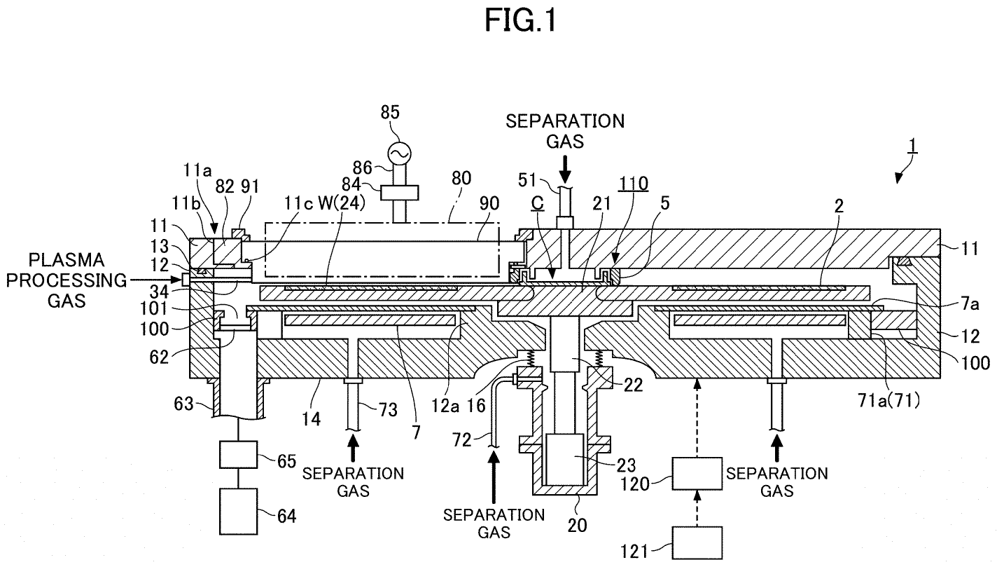

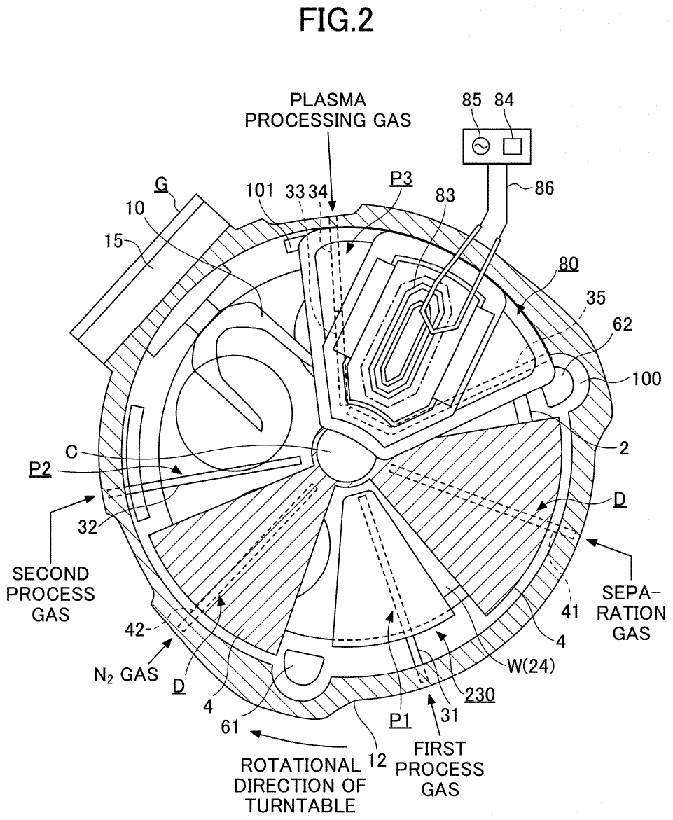

FIG. 1 is a schematic vertical cross-sectional view illustrating an example of a plasma processing apparatus according to an embodiment of the present invention. FIG. 2 is a schematic plan view illustrating an example of the plasma processing apparatus according to the embodiment. In FIG. 2, for convenience of explanation, a depiction of a top plate 11 is omitted.

As illustrated in FIG. 1, the plasma processing apparatus of the embodiment includes a vacuum chamber 1 having a substantially circular planar shape, and a susceptor 2 that is disposed in the vacuum chamber 1 such that the rotational center of the susceptor 2 coincides with the center of the vacuum chamber 1. The susceptor 2 rotates wafers W placed thereon by rotating around its rotational center.

The vacuum chamber 1 is a process chamber to accommodate wafers W therein and to perform a plasma process on a film or the like deposited on surfaces of the wafers W. The vacuum chamber 1 includes a top plate (ceiling) 11 that faces recesses 24 formed in a surface of the susceptor 2, and a chamber body 12. A ring-shaped seal member 13 is provided at the periphery of the upper surface of the chamber body 12. The top plate 11 is configured to be attachable to and detachable from the chamber body 12. The diameter (inside diameter) of the vacuum chamber 1 in plan view is, for example, about 1100 mm, but is not limited to this.

A separation gas supply pipe 51 is connected to the center of the upper side of the vacuum chamber 1 (or the center of the top plate 11). The separation gas supply pipe 51 supplies a separation gas to a central area C in the vacuum chamber 1 to prevent different process gases from mixing with each other in the central area C.

A central part of the susceptor 2 is fixed to an approximately-cylindrical core portion 21. A rotational shaft 22 is connected to a lower surface of the core portion 21 and extends in the vertical direction. The susceptor 2 is configured to be rotatable by a drive unit 23 about the vertical axis of the rotational shaft 22, in a clockwise fashion in the example of FIG. 2. The diameter of the susceptor 2 is, for example, but is not limited to, about 1000 mm.

The rotational shaft 22 and the drive unit 23 are housed in a case body 20. An upper-side flange of the case body 20 is hermetically attached to the lower surface of a bottom part 14 of the vacuum chamber 1. A purge gas supply pipe 72 is connected to the case body 20. The purge gas supply pipe 72 supplies a purge gas (separation gas) such as nitrogen gas or argon gas to an area below the susceptor 2.

A part of the bottom part 14 of the vacuum chamber 1 surrounding the core portion 21 forms a ring-shaped protrusion 12a that protrudes so as to approach the susceptor 2 from below.

Circular recesses 24 (or substrate receiving areas), where the wafers W having a diameter of, for example, 300 mm are placed, are formed in the upper surface of the susceptor 2. A plurality of (e.g., five) recesses 24 are provided along the rotational direction of the susceptor 2. Each of the recesses 24 has an inner diameter that is slightly (e.g., from 1 mm to 4 mm) greater than the diameter of the wafer W. The depth of the recess 24 is substantially the same as or greater than the thickness of the wafer W. Accordingly, when the wafer W is placed in the recess 24, the height of the upper surface of the wafer W becomes substantially the same as or lower than the height of the upper surface of the susceptor 2 where the wafers W are not placed. When the depth of the recess 24 is excessively greater than the thickness of the wafer W, it may adversely affect film deposition. Therefore, the depth of the recess 24 is preferably less than or equal to about three times the thickness of the wafer W. Through holes (not illustrated in the drawings) are formed in the bottom of the recess 24 to allow a plurality of (e.g., three) lifting pins (which are described later) to pass through. The lifting pins raise and lower the wafer W.

As illustrated in FIG. 2, a first process area P1, a second process area P2 and a third process area P3 are provided apart from each other along the rotational direction of the susceptor 2. Because the third process area P3 is a plasma processing area, it may be also referred to as a plasma processing area P3 hereinafter. A plurality of (e.g., seven) gas nozzles 31, 32, 33, 34, 35, 41, and 42 made of, for example, quartz are arranged at intervals in a circumferential direction of the vacuum chamber 1. The gas nozzles 31 through 35, 41, and 42 extend radially, and are disposed to face areas that the recesses 24 of the susceptor 2 pass through. The nozzles 31 through 35, 41, and 42 are placed between the susceptor 2 and the top plate 11. Here, each of the gas nozzles 31 through 35, 41, and 42 extends horizontally from the outer wall of the vacuum chamber 1 toward the central area C so as to face the wafers W. On the other hand, the gas nozzle 35 extends from the outer wall of the vacuum chamber 1 toward the central area C, and then bends and extends linearly along the central area C in a counterclockwise fashion (opposite direction of the rotational direction of the susceptor 2). In the example of FIG. 2, plasma processing gas nozzles 33 and 34, a plasma processing gas nozzle 35, a separation gas nozzle 41, a first process gas nozzle 31, a separation gas nozzle 42 and a second process gas nozzle 32 are arranged in a clockwise fashion (the rotational direction of the susceptor 2) from a transfer opening 15 in this order. Here, a gas supplied from the second process gas nozzle 32 is often similar to a gas supplied from the plasma processing gas nozzles 33 through 35, but the second process gas nozzle 32 need not be provided in a case where the plasma processing gas nozzles 33 through 35 sufficiently supply the gas.

Also, the plasma processing gas nozzles 33 to 35 may be substituted with a single plasma processing gas nozzle. In this case, for example, a plasma processing gas nozzle extending from the outer peripheral wall of the vacuum chamber 1 toward the central region C may be disposed, similar to the second process gas nozzle 32.

The first process gas nozzle 31 forms a “first process gas supply part”. Also, the second process gas nozzle 32 forms a “second process gas supply part”. Each of the plasma processing gas nozzles 33, 34 and 35 forms a “plasma processing gas supply part”. Each of the separation gas nozzles 41 and 42 forms a “separation gas supply part”.

Each of the gas nozzles 31 through 35, 41, and 42 is connected to gas supply sources (not illustrated in the drawings) via a flow control valve.

Gas discharge holes 36 for discharging a gas are formed in the lower side (which faces the susceptor 2) of each of the nozzles 31 through 35, 41, and 42. The gas discharge holes 36 are formed, for example, at regular intervals along the radial direction of the susceptor 2. The distance between the lower end of each of the nozzles 31 through 35, 41, and 42 and the upper surface of the susceptor 2 is, for example, from about 1 mm to about 5 mm.

An area below the first process gas nozzle 31 is a first process area P1 where a first process gas is adsorbed on the wafer W. An area below the second process gas nozzle 32 is a second process area P2 where a second process gas that can produce a reaction product by reacting with the first process gas is supplied to the wafer W. An area below the plasma processing gas nozzles 33 through 35 is a third process area P3 where a modification process is performed on a film on the wafer W. The separation gas nozzles 41 and 42 are provided to form separation areas D for separating the first process area P1 from the second process area P2, and separating the third process area P3 from the first process area P1, respectively. Here, the separation area D is not provided between the second process area P2 and the third process area P3. This is because the second process gas supplied in the second process area P2 and the mixed gas supplied in the third process area P3 partially contain a common component therein in many cases, and therefore the second process area P2 and the third process area P3 do not particularly have to be separated from each other by using the separation gas.

Although described in detail later, the first process gas nozzle 31 supplies a source gas that forms a principal component of a film to be deposited as a first process gas. For example, when the film to be deposited is a silicon oxide film (SiO₂), the first process gas nozzle 31 supplies a silicon-containing gas such as an organic aminosilane gas. The second process gas nozzle 32 supplies an oxidation gas such as oxygen gas and ozone gas as a second process gas. The plasma processing gas nozzles 33 through 35 supply a mixed gas containing the same gas as the second process gas and a noble gas to perform a modification process on the deposited film. For example, when the film to be deposited is the silicon oxide film (SiO₂), the plasma processing gas nozzles 33 through 35 supply a mixed gas of the oxidation gas such as oxygen gas and ozone gas being the same as the second process gas and a noble gas such as argon and helium. Because the plasma processing gas nozzles 33 to 35 are configured to supply gases to different regions on the susceptor 2, the flow ratio of the noble gas may be made to vary from region to region, and thus the modification process may be performed uniformly.

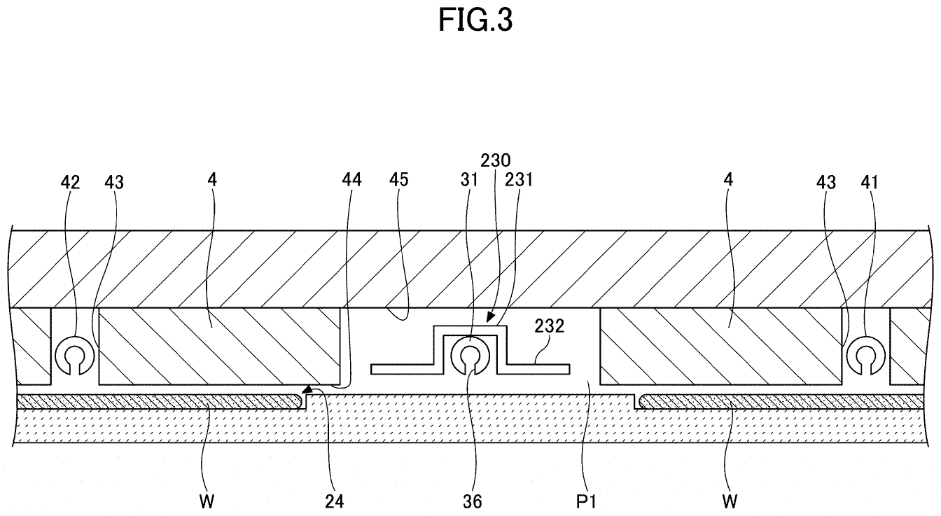

FIG. 3 illustrates a cross section of a part of the substrate processing apparatus taken along a concentric circle of the susceptor 2. More specifically, FIG. 3 illustrates a cross section of a part of the substrate processing apparatus from one of the separation areas D through the first process area P1 to the other one of the separation areas D.

Approximately pie slice-like convex portions 4 are provided on the lower surface of the top plate 11 of the vacuum chamber 1 at locations corresponding to the separation areas D. The convex portions 4 are attached to the back surface of the top plate 11. In the vacuum chamber 1, flat and low ceiling surfaces 44 (first ceiling surfaces) are formed by the lower surfaces of the convex portions 4, and ceiling surfaces 45 (second ceiling surfaces) are formed by the lower surface of the top plate 11. The ceiling surfaces 45 are located on both sides of the ceiling surfaces 44 in the circumferential direction, and are located higher than the ceiling surfaces 44.

As illustrated in FIG. 2, each of the convex portions 4 forming the ceiling surface 44 has a pie slice-like planar shape whose apex is cut off to form an arc-shaped side. Also, a groove 43 extending in the radial direction is formed in each of the convex portions 4 at the center in the circumferential direction. Each of the separation gas nozzles 41 and 42 is placed in the groove 43. A peripheral part of the convex portion 4 (a part along the outer edge of the vacuum chamber 1) is bent to form an L-shape to prevent the process gases from mixing with each other. The L-shaped part of the convex portion 4 faces the outer end surface of the susceptor 2 and is slightly apart from the chamber body 12.

A nozzle cover 230 is provided above the first process gas nozzle 31. The nozzle cover 230 causes the first process gas to flow along the wafer W, and causes the separation gas to flow near the top plate 11 instead of near the wafer W. As illustrated in FIG. 3, the nozzle cover 230 includes an approximately-box-shaped cover 231 having an opening in the lower side to accommodate the first process gas nozzle 31, and current plates 232 connected to the upstream and downstream edges of the opening of the cover body 231 in the rotational direction of the susceptor 2. A side wall of the cover body 231 near the rotational center of the susceptor 2 extends toward the susceptor 2 to face a tip of the first process gas nozzle 31. Another side wall of the cover 231 near the outer edge of the susceptor 2 is partially cut off so as not to interfere with the first process gas nozzle 31.

As illustrated in FIG. 2, a plasma generating device 80 is provided above the plasma processing gas nozzles 33 through 35 to convert a plasma processing gas discharged into the vacuum chamber 1 to plasma.

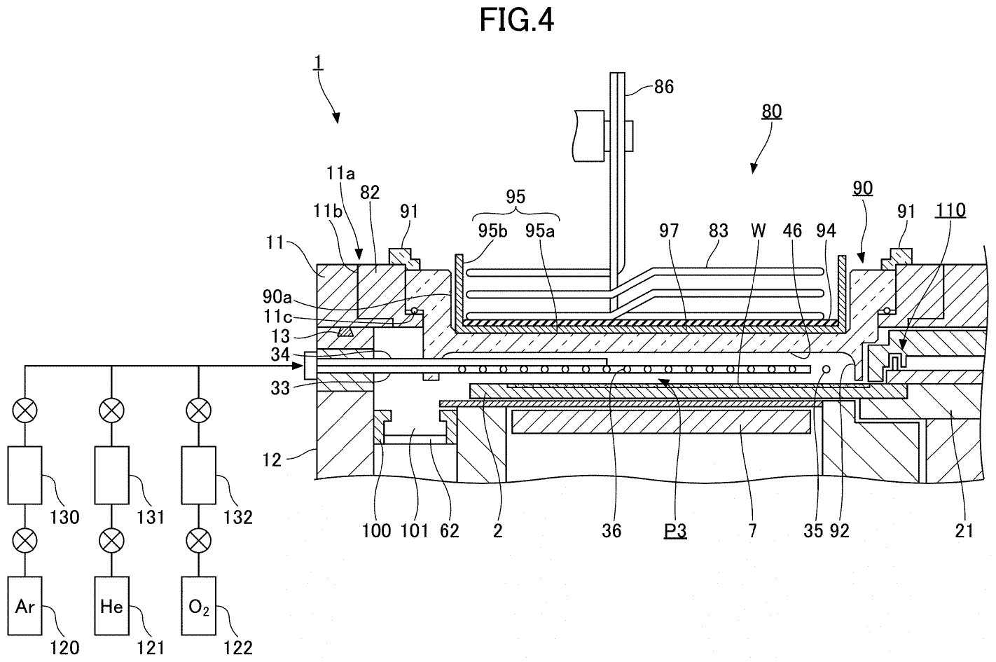

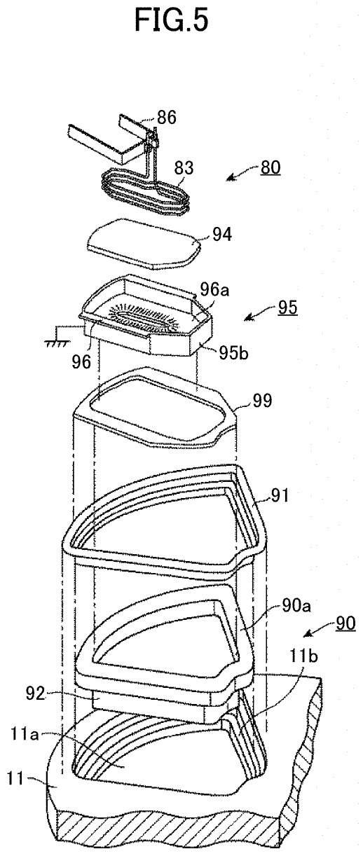

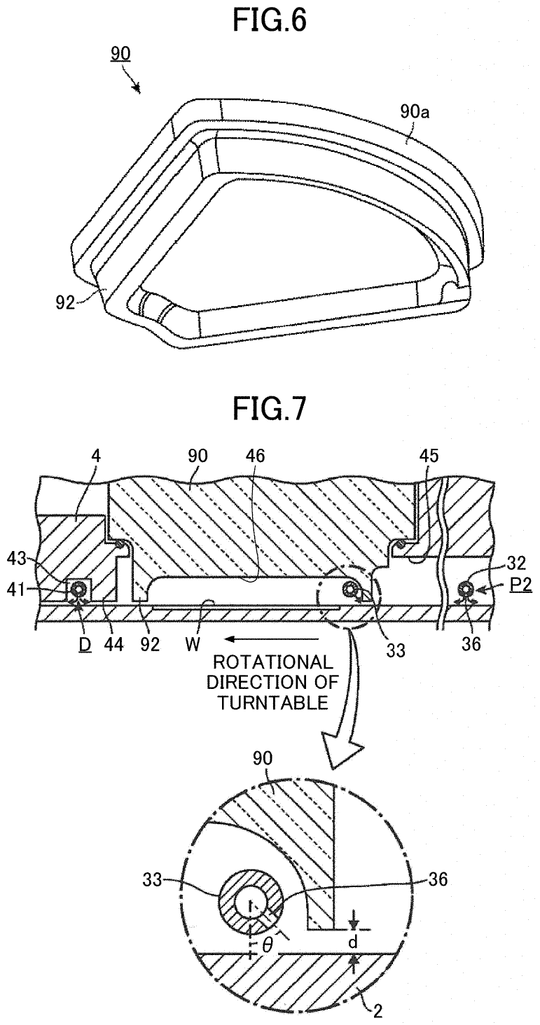

FIG. 4 is a vertical cross-sectional view of an example of the plasma generating device 80. FIG. 5 is an exploded perspective view of an example of the plasma generating device 80. FIG. 6 is a perspective view of an example of a housing 90 of the plasma generating device 80.

The plasma generating device 80 is configured by winding an antenna 83 made of a metal wire or the like, for example, three times around a vertical axis in a coil form. In plan view, the plasma generating device 80 is disposed to surround a strip-shaped area extending in the radial direction of the susceptor 2 and to extend across the diameter of the wafer W on the susceptor 2.

The antenna 83 is connected through a matching box 84 to a high frequency power source 85 that has, for example, a frequency of 13.56 MHz and output power of 5000 W. The antenna 83 is hermetically separated from the inner area of the vacuum chamber 1. As illustrated in FIGS. 1, 2, and 4, a connection electrode 86 electrically connects the antenna 83, the matching box 84, and the high frequency power source 85.

The antenna 83 has a foldable configuration at the top and the bottom, and has a lifting mechanism enabling the antenna 83 to be folded automatically at the top and the bottom. However, in FIG. 2, details thereof are omitted. The details are described later.

As illustrated in FIGS. 4 and 5, an opening 11a having an approximately pie slice-like shape in plan view is formed in the top plate 11 above the plasma processing gas nozzles 33 through 35.

As illustrated in FIG. 4, a ring-shaped member 82 is hermetically attached to the periphery of the opening 11a. The ring-shaped member 82 extends along the periphery of the opening 11a. The housing 90 is hermetically attached to the inner circumferential surface of the ring-shaped member 82. That is, the outer circumferential surface of the ring-shaped member 82 faces an inner surface 11b of the opening 11a of the top plate 11, and the inner circumferential surface of the ring-shaped member 82 faces a flange part 90a of the housing 90. The housing 90 is placed via the ring-shaped member 82 in the opening 11a to enable the antenna 83 to be placed at a position lower than the top plate 11. The housing 90 may be made of a dielectric material such as quartz. The bottom surface of the housing 90 forms a ceiling surface 46 of the plasma processing area P3.

As illustrated in FIG. 6, an upper peripheral part surrounding the entire circumference of the housing 90 extends horizontally to form the flange part 90a. Moreover, a central part of the housing 90 in plan view is recessed toward the inner area of the vacuum chamber 1.

The housing 90 is arranged so as to extend across the diameter of the wafer W in the radial direction of the susceptor 2 when the wafer W is located under the housing 90. A seal member 11c such as an O-ring is provided between the ring-shaped member 82 and the top plate 11.

The internal atmosphere of the vacuum chamber 1 is hermetically sealed by the ring-shaped member 82 and the housing 90. As illustrated in FIG. 5, the ring-shaped member 82 and the housing 90 are placed in the opening 11a, and the entire circumference of the housing 90 is pressed downward via a frame-shaped pressing member 91 that is placed on the upper surfaces of the ring-shaped member 82 and the housing 90 and extends along a contact region between the ring-shaped member 82 and the housing 90. The pressing member 91 is fixed to the top plate 11 with, for example, bolts (not illustrated in the drawing). As a result, the internal atmosphere of the vacuum chamber 1 is sealed hermetically. In FIG. 5, a depiction of the ring-shaped member 82 is omitted for simplification.

As illustrated in FIG. 6, the housing 90 also includes a protrusion 92 that extends along the circumference of the housing 90 and protrudes vertically from the lower surface of the housing 90 toward the susceptor 2. The protrusion 92 surrounds the second process area P2 below the housing 90. The plasma processing gas nozzles 33 through 35 are accommodated in an area surrounded by the inner circumferential surface of the protrusion 92, the lower surface of the housing 90, and the upper surface of the susceptor 2. A part of the protrusion 92 near a base end (at the inner wall of the vacuum chamber 1) of each of the plasma processing gas nozzles 33 through 35 is cut off to form an arc-shaped cut-out that conforms to the outer shape of each of the plasma processing gas nozzles 33 through 35.

As illustrated in FIG. 4, on the lower side (i.e., the second process area P2) of the housing 90, the protrusion 92 is formed along the circumference of the housing 90. The protrusion 92 prevents the seal member 11c from being directly exposed to plasma, i.e., isolates the seal member 11c from the second process area P2. This causes plasma to pass through an area under the protrusion 92 even when plasma spreads from the second process area P2 toward the seal member 11c, thereby deactivating the plasma before reaching the seal member 11c.

Moreover, as illustrated in FIG. 4, the plasma processing gas nozzles 33 through 35 are provided in the third process area P3 under the housing 90, and are connected to an argon gas supply source 120, a helium gas supply source 121, and an oxygen gas supply source 122, respectively. Furthermore, corresponding flow controllers 130, 131 and 132 are provided between the plasma processing gas nozzles 33 through 35 and the argon gas supply source 120, the helium gas supply source 121, and the oxygen gas supply source 122, respectively. Ar gas, He gas, and O₂ gas are supplied from the argon gas supply source 120, the helium gas supply source 121, and the oxygen gas supply source 122 to each of the plasma processing gas nozzles 33 through 35 at predetermined flow rates (mixing ratios, mix proportions) through each of the flow controllers 130, 131 and 132, and flow rates thereof are determined depending on supplied areas.

When a single plasma processing gas nozzle is used, for example, the mixture of the above-described Ar gas, He gas, and O₂ gas is supplied to the single plasma processing gas nozzle.

FIG. 7 is a vertical cross-sectional view of the vacuum chamber 1 taken along the rotational direction of the susceptor 2. As illustrated in FIG. 7, because the susceptor 2 rotates in a clockwise fashion during the plasma process, N₂ gas or Ar gas is likely to intrude into an area under the housing 90 from a clearance between the susceptor 2 and the protrusion 92 by being brought by the rotation of the susceptor 2. To prevent N₂ or Ar gas from intruding into the area under the housing 90 through the clearance, a gas is discharged to the clearance from the area under the housing 90. More specifically, as illustrated in FIGS. 4 and 7, the gas discharge holes 36 of the plasma processing gas nozzle 33 are arranged to face the clearance, that is, to face the upstream side in the rotational direction of the susceptor 2 and downward. A facing angle θ of the gas discharge holes 36 of the plasma processing gas nozzle 33 relative to the vertical axis may be, for example, about 45 degrees as illustrated in FIG. 7, or may be about 90 degrees so as to face the inner side wall of the protrusion 92. In other words, the facing angle θ of the gas discharge holes 36 may be set at an appropriate angle capable of properly preventing the intrusion of N₂ gas or Ar gas in a range from 45 to 90 degrees depending on the intended use.

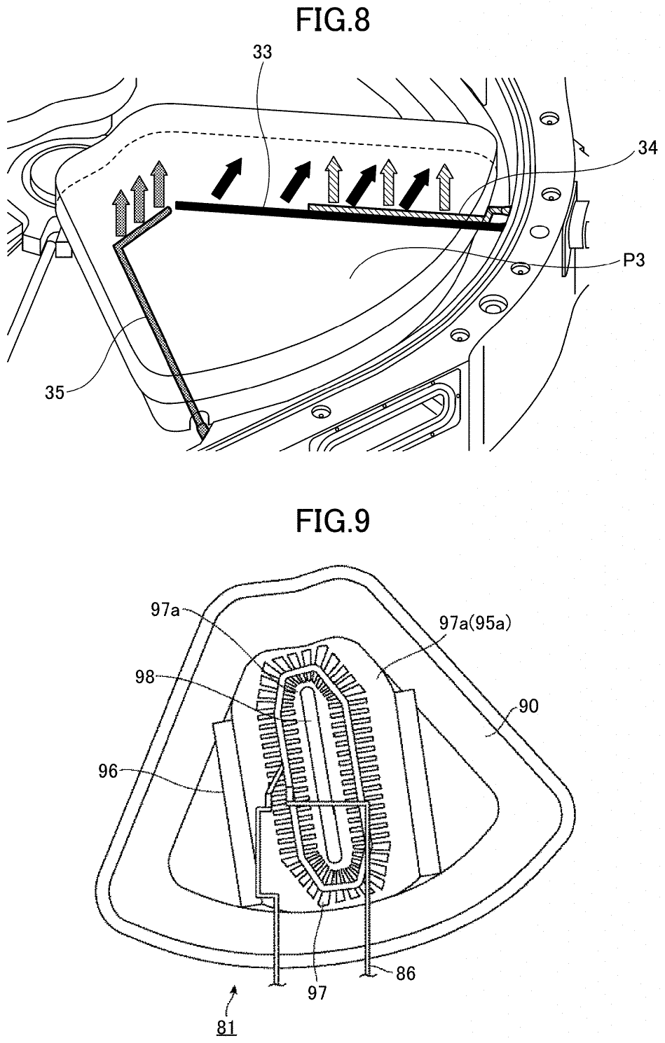

FIG. 8 is an enlarged perspective view illustrating the plasma processing gas nozzles 33 through 35 provided in the plasma processing area P3. As illustrated in FIG. 8, the plasma processing gas nozzle 33 is a nozzle capable of covering the whole of the recess 24 in which the wafer W is placed, and supplying a plasma processing gas to the entire surface of the wafer W. On the other hand, the plasma processing gas nozzle 34 is a nozzle provided slightly above the plasma processing gas nozzle 33 so as to approximately overlap with the plasma processing gas nozzle 33. The length of the plasma processing gas nozzle 34 is about half the length of the plasma processing gas nozzle 33. The plasma processing gas nozzle 35 extends from the outer peripheral wall of the vacuum chamber 1 along the radius of the downstream side of the pie slice-like plasma process area P3 in the rotational direction of the susceptor 2, and has a shape bent linearly along the central area C after reaching the neighborhood of the central area C. Hereinafter, for convenience of distinction, the plasma processing gas nozzle 33 covering the whole area may be referred to as a base nozzle 33, and the plasma processing gas nozzle 34 covering only the outer area may be referred to as an outer nozzle 34. Also, the plasma processing gas nozzle 35 extending to the inside may be referred to as an axis-side nozzle 35.

The base nozzle 33 is a gas nozzle for supplying a plasma processing gas to the whole surface of the wafer W. As illustrated in FIG. 7, the base gas nozzle 33 discharges the plasma processing gas toward the protrusion 92 forming the side surface separating the plasma process area P3 from the other area.

On the other hand, the outer nozzle 34 is a nozzle for supplying a plasma processing gas selectively to an outer area of the wafer W.

The axis-side nozzle 35 is a nozzle to mainly supply the plasma processing gas to the central area near the axial side of the susceptor 2 on the wafer W.

Here, when a plasma processing gas nozzle is formed as a single gas nozzle, only the base gas nozzle may be disposed.

Next, a detailed description is given below of a Faraday shield 95 of the plasma generating device 80. As illustrated in FIGS. 4 and 5, a Faraday shield 95 is provided on the upper side of the housing 90. The Faraday shield 95 is grounded, and is composed of a conductive plate-like part such as a metal plate (e.g., copper plate) that is shaped to roughly conform to the internal shape of the housing 90. The Faraday shield 95 includes a horizontal surface 95a that extends horizontally along the bottom surface of the housing 90, and a vertical surface 95b that extends upward from the outer edge of the horizontal surface 95a and surrounds the horizontal surface 95a. The Faraday shield 95 may be configured to be, for example, a substantially hexagonal shape in a plan view.

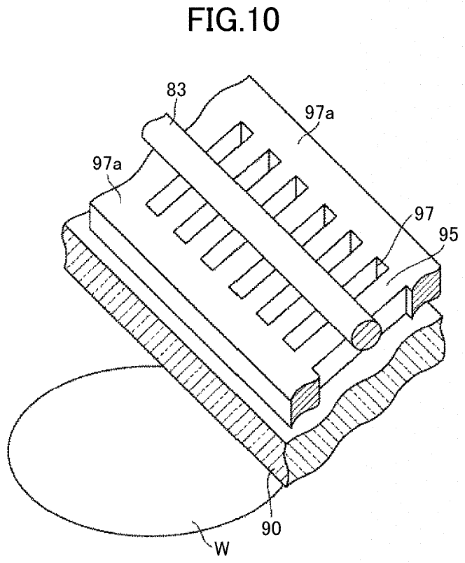

FIG. 9 is a plan view of an example of a plasma generator of a plasma processing apparatus according to an embodiment of the present disclosure. FIG. 10 is a perspective view of a part of the Faraday shield 95 provided in the plasma generating device 80.

Viewing the Faraday shield 95 from the rotational center of the susceptor 2, the right and left upper ends of the Faraday shield 95 extend horizontally rightward and leftward, respectively, to form supports 96. A frame 99 is provided between the Faraday shield 95 and the housing 90 to support the supports 96 from below. The frame 99 is supported by a part of the housing 90 near the central area C and a part of the flange part 90a near the outer edge of the susceptor 2.

When an electric field reaches the wafer W, for example, electric wiring and the like formed inside the wafer W may become electrically damaged. To prevent this problem, as illustrated in FIG. 10, a plurality of slits 97 is formed in the horizontal surface 95a. The slits 97 prevent an electric-field component of an electric field and a magnetic field (electromagnetic field) generated by the antenna 83 from reaching the wafer W below the Faraday shield 95, and allow a magnetic field component of the electromagnetic field to reach the wafer W.

As illustrated in FIGS. 9 and 10, the slits 97 extend in directions that are orthogonal to the direction in which the antenna 83 is wound, and are arranged to form a circle below the antenna 83. The width of each slit 97 is set at a value that is about 1/10000 or less of the wavelength of a high frequency supplied to the antenna 83. Circular electrically-conducting paths 97a made of, for example, a grounded conductor are provided at the ends in the length direction of the slits 97 to close the open ends of the slits 97. An opening 98 is formed in an area of the Faraday shield 95 where the slits 97 are not formed, i.e., an area surrounded by the antenna 83. The opening 98 is used to check whether plasma is emitting light. In FIG. 2, the slits 97 are omitted for simplification, but an area where the slits 97 are formed is indicated by a dashed-dotted line.

As illustrated in FIG. 5, an insulating plate 94 is stacked on the horizontal surface 95a of the Faraday shield 95. The insulating plate 94 is made of, for example, quartz having a thickness of about 2 mm, and is used for insulation between the Faraday shield 95 and the plasma generating device 80 disposed above the Faraday shield 95. Thus, the plasma generating device 80 is arranged to cover the inside of the vacuum chamber 1 (i.e., the wafer W on the susceptor 2) through the housing 90, the Faraday shield 95, and the insulating plate 94.

Next, an example of an antenna device 81 for holding an antenna according to an embodiment of the present disclosure and a plasma generating device 80 will be described.

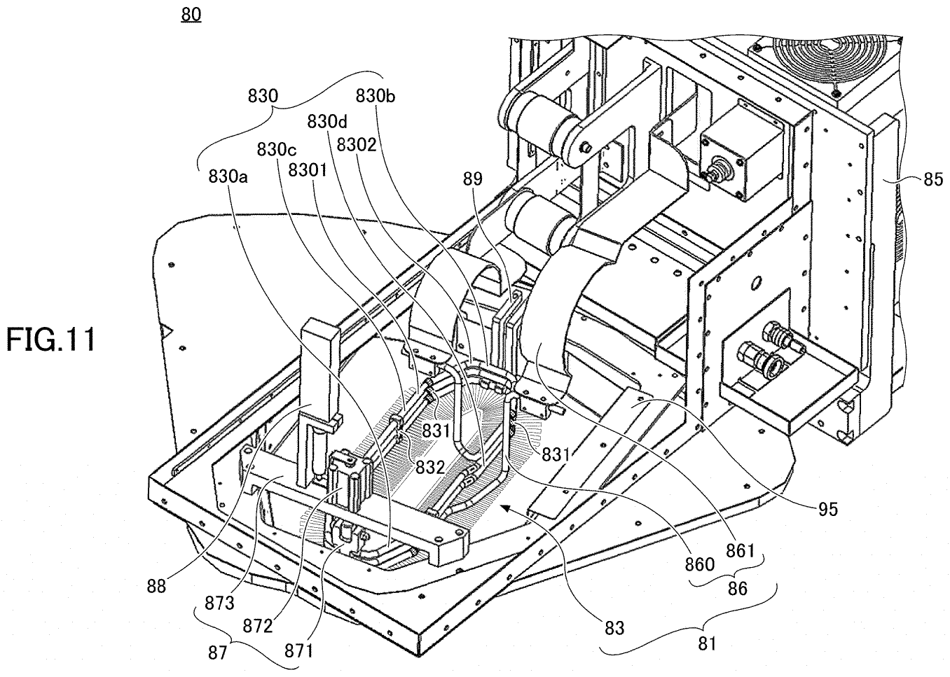

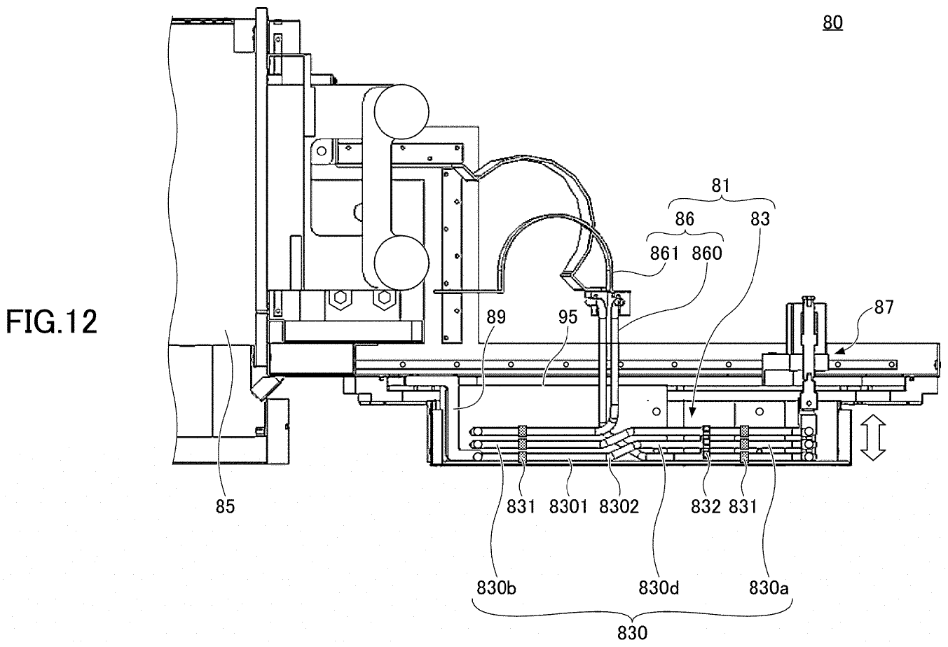

FIG. 11 is a perspective view of an antenna device 81 and a plasma generating device 80. FIG. 12 is a side view of an antenna device 81 and a plasma generating device 80.

The antenna device 81 includes an antenna 83, a connection electrode 86, a lifting mechanism 87, a linear encoder 88, and a fulcrum jig 89.

Also, the plasma generating device 80 further includes the antenna device 81, a matching box 84, and a radio frequency power source 85.

The antenna 83 includes an antenna member 830, a coupling member 831 and a spacer 832. The antenna 83 is generally configured in a coil shape, or a track-like shape, and is planar in an elongate annular shape having a longitudinal direction and a short-side direction (or a width direction). The planar shape may be an ellipse having an angle or a shape close to a rectangular frame having an angle. Such a track-like shape of antenna 83 is formed by coupling the antenna members 830. The antenna member 830 is part of the antenna 83 and the antenna 83 is formed by connecting ends of a plurality of small antenna members 830 extending along the track-like shape. The antenna member 830 includes a straight portion 8301 having a straight shape and curved portion 8302 having a curved shape for bending and connecting the straight portions 8301.

Then, by combining and connecting the straight portions 8301 and the curved portions 8302, the antenna members 830 are connected to both ends 830a and 830b and the central portions 830c and 830d to form a track-like shape as a whole. In FIG. 11, the antenna 83 has, as an overall shape, both ends 830a and 830b having a shape close to an arc, and the central portions 830c and 830d having a linear shape. The antenna members 830a and 830b at the ends of the antenna members 830c and 830d in the shape close to the arc are connected to each other with the antenna members 830c and 830d in the central linear shape, and the central antenna members 830c and 830d are substantially parallel to each other. The antenna 83 is generally shaped such that the antenna members 830c and 830d have a long side and the antenna members 830a and 830b have a short side.

As illustrated in FIG. 11, the antenna members 830a and 830b are formed in a shape that approximates an arc shape where three straight portions 8301 are connected via two curved portions 8302. The antenna member 830c is composed of one long straight portion 8301. As illustrated in FIGS. 11 and 12, the antenna member 830d is formed by forming two long straight portions 8301 and one short straight portion between them with steps at the top and the bottom, so that two small curved portions 8302 are formed by being coupled to each other.

The antenna member 830 forms a multi-stage track-like shape as a whole, and in FIGS. 11 and 12, an antenna member 830 is illustrated forming a three-stage track-like shape.

The coupling member 831 is a member for connecting adjacent antenna members 830 to each other and is made with a material that is conductive and can be deformed. The coupling member 831 may be made with, for example, a flexible substrate or the like, and may be made with a copper material. The copper material is a highly conductive and soft material, and is suitable for coupling the antenna members 830 to each other.

Because the coupling members 831 are made with a flexible material, it is possible to bend the antenna members 830 with the coupling members 831 as a fulcrum. This allows the antenna members 830 to be maintained in a bent state at the point of the coupling members 831, while allowing the configuration of the antenna 83 to be varied. The distance between the antenna 83 and the wafer W is likely to affect the intensity of the plasma process. When the antenna 83 is brought close to the wafer W, the intensity of the plasma process is likely to increase, and when the antenna 83 is moved away from the wafer W, the intensity of the plasma process is likely to decrease.

Further, the method of determining the shape of the antenna 83 and the details of the shape will be described below.

When the wafer W is loaded on the recess 24 of the susceptor 2 and the susceptor 2 is rotated to perform the plasma process, the wafer W is positioned along the circumferential direction of the susceptor 2, and the moving speed of the center side of the susceptor 2 is low and the moving speed of the outer side is high. Thus, the intensity (or processing amount) of the plasma process at the center of the wafer W, which is irradiated with plasma for a long time, is likely to be higher than the intensity of the plasma process at the outer periphery. To correct this, for example, if the antenna member 830a disposed on the central side is folded upwardly and the antenna member 830b disposed on the peripheral side is folded downwardly, the central plasma processing intensity is reduced; the peripheral plasma processing intensity is increased, and the overall plasma processing amount is uniform in the radial direction of the susceptor 2.

In FIG. 11, four coupling members 831 are provided for connecting four antenna members 830a to 830d to each other. However, the number of antenna members 830 and coupling members 831 may be increased or decreased depending on the application. At a minimum, the antenna members 830a and 830b at both ends may be present, which may be configured in a long U-shaped shape extending not only at both ends but also to the central portion, and the two antenna members 830a and the antenna members 830b are connected by the two coupling members 831. Further, if the shape of the antenna 83 is desired to be varied to a greater extent, four antenna members 830 may be disposed at the center to increase the bendable portion.

In any case, facing coupling members 831 are preferably disposed at the same position in the longitudinal direction, that is, equal in length in the longitudinal direction of the facing antenna members 830. As noted above, the antenna 83 is preferably configured to change its height in the longitudinal direction, while using the bending points facing each other in the short-side direction and coinciding with each other in the longitudinal direction. In this embodiment, the coupling members 831 coupling the antenna member 830a to the antenna member 830c and the coupling members 831 coupling the antenna member 830a to the antenna member 830d are configured to face each other in the short-side direction and be in the same position in the longitudinal direction. Similarly, the coupling member 831, which couples the antenna member 830b to the antenna member 830c, and the coupling member 831, which couples the antenna member 830b to the antenna member 830d, are also configured to face each other in the short-side direction and be in the same position in the longitudinal direction. Such an arrangement allows the shape of the antenna 83 to be varied to adjust the intensity of the plasma process in the longitudinal direction.

However, when the bending portion is shifted in an oblique direction and a deformation into a parallelogram shape, for example, is desired, it is possible to set the longitudinal positions of the coupling member 831 to different positions on the 830c side and the 830d side in the oblique direction instead of facing each other in the short-side direction.

A spacer 832 is a member for separating multi-stage antenna members 830 disposed at an upper stage and a lower stage from each other so that even if antenna 83 is deformed, the antenna members 830 do not contact the upper and lower stages and do not cause a short circuit.

The lifting mechanism 87 is a vertical motion mechanism for moving the antenna member 830 up and down. The lifting mechanism 87 includes an antenna retainer 870, a drive unit 871, and a frame 872. The antenna retainer 870 is the retaining portion of the antenna 83 and the drive unit 871 is a driving part for moving the antenna 83 up and down through the antenna retainer 870. The antenna retainer 870 may have various configurations as long as the antenna retainer 870 can hold the antenna member 830 of the antenna 83, but may be constructed to hold the antenna member 830 around the perimeter of the antenna member 830, for example, as illustrated in FIG. 12.

The drive unit 871 may also use various drivers as long as the antenna members 830 can be moved up and down, for example, an air cylinder for air drive may be used. In FIG. 12, an example is illustrated in which an air cylinder is applied to the drive unit 871 of the lifting mechanism 87. In addition, a motor or the like may be used for the lifting mechanism 87.

A frame 872 is a support for holding the drive unit 871, and holds the drive unit 871 at an appropriate position. The antenna retainer 870 is retained by the drive unit 871.

The lifting mechanism 87 is disposed for at least two or more of the antenna members 830a to 830d individually. In this embodiment, deformation of the antenna 83 is performed automatically using the lifting mechanism 87, rather than being adjusted by the operator. Thus, to deform the antenna 83 into various shapes, preferably, each of the antenna members 830a to 830d individually includes the lifting mechanism 87, each of which operates independently. Thus, the lifting mechanism 87 is preferably disposed for each of the antenna members 830a to 830d, and the lifting mechanism 87 is disposed for at least two of the antenna members 830a to 830d even when the lifting mechanism 87 is not disposed for each of the antenna members 830a to 830d.

In FIGS. 11 and 12, only a single lifting mechanism 87 is shown, but actually, the lifting mechanism 87 is disposed for each of the antenna members 830a to 830d to be bent. For example, if a lifting mechanism 87 for moving the antenna member 830a up and down is disposed at the center of the rotational direction of the susceptor 2 and a lifting mechanism 87 for moving the antenna members 830c and 830d up and down is further disposed, the antenna members 830a, 830c and 830d can be deformed in any shape. In this case, for example, when it is desired to bend the antenna member 830a upwardly at the central end, the lifting mechanism 87 corresponding to the antenna member 830a may be pulled up, and the lifting mechanisms 87 corresponding to the antenna members 830c and 830d may be fixed or lowered, and the antenna members 830 may be deformed by cooperating with a plurality of lifting mechanisms 87. It is not necessary to do so when the coupling member 831 is sufficiently soft to allow the antenna 83 to bend only by the corresponding lifting mechanism 87. However, while the coupling member 831 may be deformable, when it is necessary to apply some force to the deformation, the plurality of lifting mechanism 87 may cooperate to perform the bending action of the antenna 83.

The bending of the antenna 83 is performed by changing the angle formed between the antenna members 830a to 830d on both sides of the coupling member 831, with the coupling member 831 serving as the fulcrum.

A linear encoder 88 is a device that detects the position of the linear axis and outputs position information. This allows accurate measurement of the distance of the antenna member 830a from the top face of the Faraday shield 95. The linear encoder 88 may be disposed at any position where precise position information is desired, and a plurality of the linear encoders may be disposed. The linear encoder 88 may be any type including an optical, a magnetic, or an electromagnetic inductive type, as long as the position and height of the antenna 83 can be measured. Additionally, as long as the position and height of the antenna 83 can be measured, a height measuring unit other than the linear encoder 88 may be used.

The fulcrum jig 89 is a member for pivotally securing the lowermost antenna member 830. This facilitates tilting the antenna 83. Generally, the fulcrum jig 89 is provided to support the antenna member 830b of the lowermost stage at the end of the outer peripheral side. This is because, as noted above, the antenna 83 is often deformed to raise the center side. However, it is not mandatory to provide the fulcrum jig 89, but rather it is preferable to provide the lifting mechanism 87 that moves the antenna member 830b up and down.

The connection electrode 86 includes an antenna connecting part 860 and an adjustment busbar 861. The connection electrode 86 is a connection wire that serves as a framing to supply the antenna 83 with high frequency power output from the radio frequency power source 85. The antenna connecting part 860 is an interconnection directly connected to the antenna 83, and the adjustment busbar 861 is a part of the antenna connecting part 860 having a resilient structure to absorb the deformation when the antenna connecting part 860 is moved up and down by the vertical movement of the antenna 83. Because the antenna connecting part 860 is an electrode, the antenna connecting part 860 is made with an electrically conductive material such as metal.

Thus, antenna device 81 and plasma generating device 80 may be used that can automatically transform the shape of the antenna 83 into any shape.

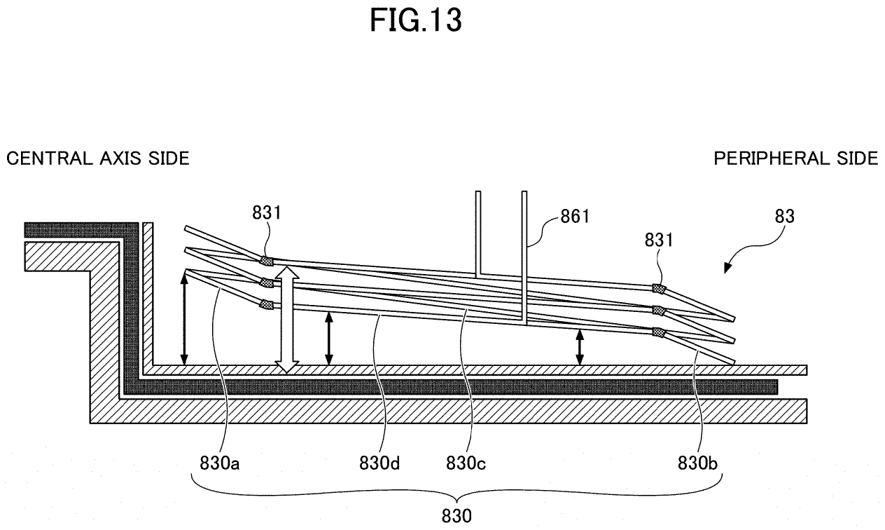

FIG. 13 is a side view of an antenna 83 according to an embodiment of the present disclosure. As illustrated in FIG. 13, the bending angle of the antenna member 830 may be varied with the coupling member 831 as well as the height of the antenna member 830 depending on the location.

[Antenna Shape]

Next, an antenna 83 according to embodiments of the present invention will be described. As noted above, the antenna 83 in accordance with this embodiment can be deformed in three dimensions.

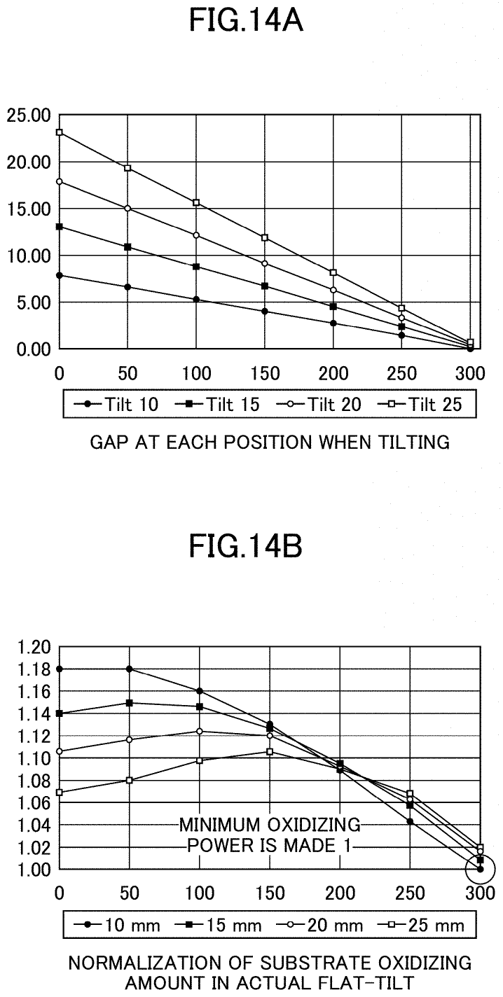

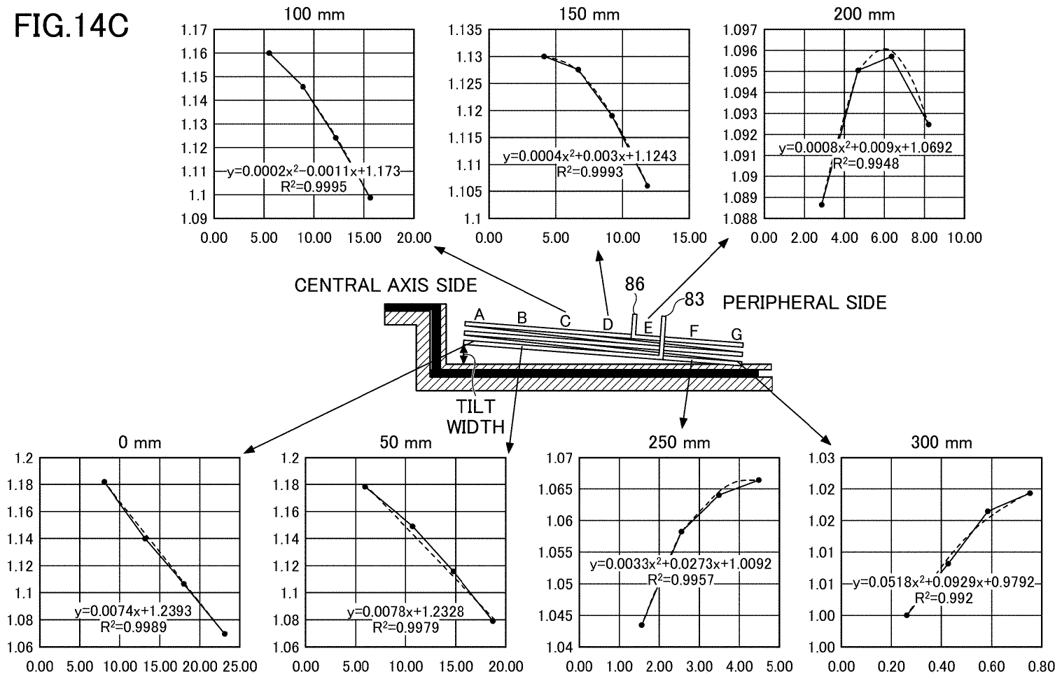

FIGS. 14A to 14C show diagrams for explaining a method for determining a shape of an antenna according to the present embodiment. Conventionally, the uniformity across a surface of a wafer W of a plasma process has attempted to be improved by raising the antenna 83 on the central axis side of the susceptor 2 and lowering the antenna 83 on the outer peripheral side. This is because the moving speed of the wafer W on the outer peripheral side is faster than that on the central axis side, and thus plasma irradiation on the outer peripheral side is smaller than that on the central axis side.

The amount of plasma processing was considered to be proportional to the distance from the top plate 11 of the vacuum chamber 1 (precisely the bottom face of the housing 90).

FIG. 14A shows the distance from the bottom in the radial direction (longitudinal direction) of the antenna 83 when the antenna 83 is tilted (also referred to as “tilting”). Conventionally, it was believed that the amount of plasma processing varies proportionally thereto.

However, in fact, the study of the inventors has found that the amount of plasma processing changes as shown in FIG. 14B.

The horizontal axis of FIG. 14B shows the distance from the center where the central axis side of the susceptor 2 is 0 mm, and the outer circumference is 300 mm when the wafer W is loaded on the recess 24 of the susceptor 2. The vertical axis indicates the oxidizing amount when the minimum oxidizing amount is 1.

As shown in FIG. 14B, the oxidizing amount varies on the central axis (closer to 0), but the change in the oxidizing amount decreases as the measurement point moves toward the outer circumference, and the slope is reversed at 200 mm.

In FIG. 14C, the antenna 83 includes a measurement point every 50 mm, and the symbols A, B, C, D, E, F, and G are added to the positions 0 mm, 50 mm, 100 mm, 150 mm, 200 mm, 250 mm, and 300 mm, respectively. In the graph corresponding to the measurement points A to G, the horizontal axis indicates the distance from the bottom face of the housing 90 at each measurement point, and the vertical axis indicates the oxidizing amount of the measurement point where the distance from the bottom face of the outer peripheral side where the oxidizing amount is the smallest is about 2.5 mm, and the values indicated by normalizing other oxidizing amounts are shown.

As can be seen from the graph for each measurement point, the distance from the bottom face and the decrease in the oxidizing amount are proportional at a point A on the central axis side. A point B (50 mm) and a point B (100 mm) show similar properties. However, at a point E (200 mm), a linear line deforms and is shaped like a quadratic curve. In this case, the oxidizing amount is not proportional to the distance from the bottom face of the housing 90 of the antenna 83, and has an inflection point. The oxidizing amount is likely to increase as the point of inflection approaches the bottom face (the right side of the graph), but when the point of inflection is exceeded, the oxidizing amount decreases as the distance from the bottom face approaches (the left side of the graph).

At a point F (250 mm) and point G (300 mm), the slope is reversed from the points A to C, and the shorter the distance from the bottom face, the smaller the oxidizing amount.

As described above, in order to improve the uniformity of the oxidizing amount across the surface of the wafer W, the change in the oxidizing amount corresponding to the distance from these centers is understood, and the shape of the antenna 83 needs to be set so as to generate a constant oxidizing amount depending on the distance from the center of the susceptor 2.

FIG. 14B indicates that the height of the antenna 83 needs to be relatively high in the central portion because the oxidizing amount is relatively small in proportion to the distance from the bottom face of the antenna 83, and that the height of the antenna 83 should be reduced on the peripheral side because the change in the oxidizing amount is small on the peripheral side in both cases where the antenna 83 is raised and lowered.

For example, when the oxidizing amount is set to be the same at each measurement point, a shape that improves the uniformity of the oxidizing amount across the surface of the wafer W of the antenna 83 can be understood. In other words, if the oxidizing amount is constant at each measurement point A to G, the oxidizing amount at each measurement point A to G is uniform, and a plasma process with high uniformity across the surface of the wafer W can be performed.

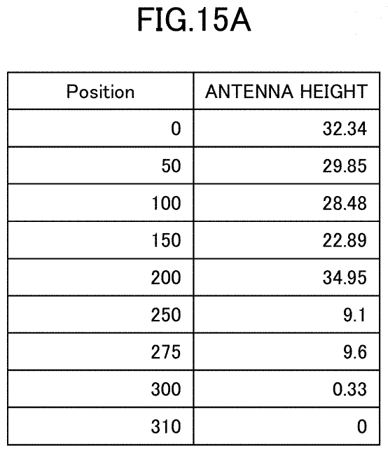

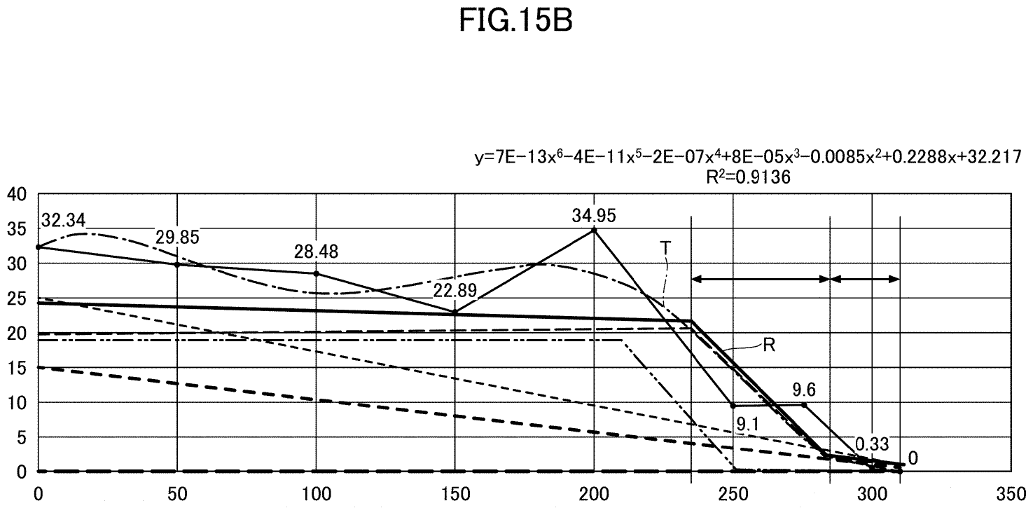

FIG. 15A is a table in which the antenna height at which the oxidizing force becomes 1 is calculated, and FIG. 15B is a plot of the table of FIG. 15A, which shows the antenna shape. The table in FIG. 15A shows the height at which the oxidizing amount is 1 at each measurement point A to G every 50 mm.

The right-hand side of FIG. 15B shows an ideal curve T plotted at the point where the oxidation power becomes 1. The ideal curve T shows the shape of the antenna 83 that can make the oxidizing amount most uniform, but because the antenna 83 is a metal, bending such as a fine curve is extremely difficult.

Therefore, the ideal curve T is approximated and the final shape R is shown by a line that can be machined. When the antenna 83 is configured to be the final shape R, because the shape of the antenna 83 is very close to the ideal curve T, the uniformity of plasma processing across the surface of the wafer W is dramatically improved.

Thus, in the antenna 83 according to the present embodiment, by defining the shape of antenna 83 such that the oxidizing amount is a predetermined value, an antenna 83 with extremely high uniformity of plasma processing across a surface of a wafer W can be configured.

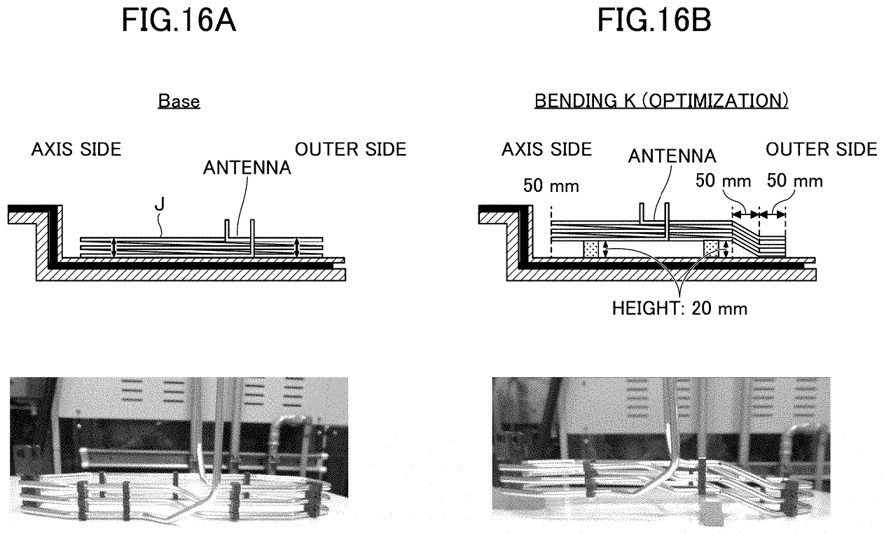

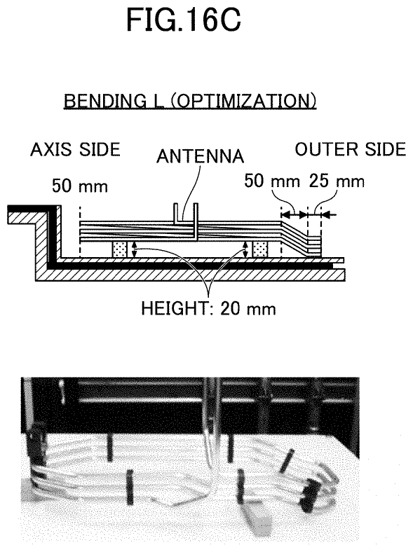

FIGS. 16A to 16C are diagrams showing an example of a method for forming an antenna 83 according to the present embodiment. FIG. 16A shows a base state in which an antenna 83 is mounted horizontally. At this stage, the shape of the antenna 83 is not bent and there is no tilt arrangement.

FIG. 16B is a first step in bending optimization. At this stage, the antenna is machined to lower the outer peripheral side, but the bending part of the outer peripheral side is machined to an even length. As will be described later, the oxidation power was actually measured and was also investigated for this shape.

FIG. 16c is a second stage in the bending optimization. At this stage, the degree of bending the outer periphery is adjusted. Specifically, the width of the outermost circumference is reduced so that the final shape R in FIG. 15B is obtained. That is, the shape of the antenna 83 is adjusted so that the length of the diagonal portion is increased and the portion close to the horizontal side of the outermost circumference is narrowed. At this stage, two patterns were produced: a shape consisting of a horizontal portion and a bent portion, and a shape forming an entire shape by adding a slight tilt to the horizontal portion and the bent portion.

As described above, the shape of the antenna 83 can be configured to be the final shape R by performing the shape adjustment of the antenna 83 in multiple stages. Oxidation power was measured at each optimization stage.

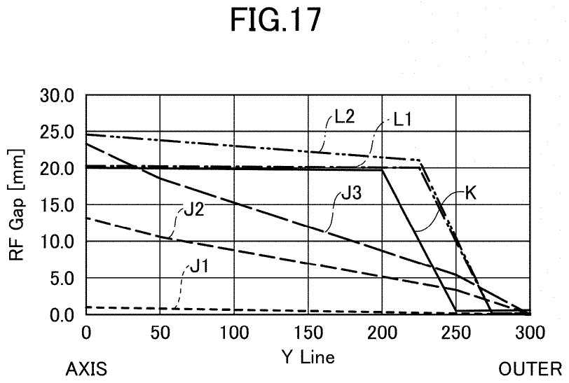

FIG. 17 is a diagram illustrating a specific shape of the optimization in FIGS. 16A to 16C. FIG. 17 shows antenna side shapes J1 to J3, K, L1, and L2.

The antennas J1 to J3 have flat shapes corresponding to the shape in FIG. 16A, and are arranged horizontally. The antenna J1 is arranged horizontally, and the distance from the central bottom face (hereinafter, referred to as a “tilt width”) is set to 15 mm for the antenna J2. The tilt width is set to 25 mm. for the antenna J3.

The antenna K has a bending shape corresponding to FIG. 16B. The antenna K has a horizontal portion extending from the center first that bends at a point of 200 mm, and then extends horizontally from a point of 250 mm, while having a width of 50 mm on the outer periphery from the point.

The antenna L1 has a bending shape corresponding to that of FIG. 16C. The antenna L1 has a bending portion on the outer peripheral side at a point of 225 mm, which is outside the bending portion of the antenna K, and a portion extending horizontally and outwardly at a point of 275 mm.

The antenna L2 is similar to the antenna L1 but has a sloped shape extending outward from the center. The shape of antenna L2 corresponds to the final shape R in FIG. 15C.

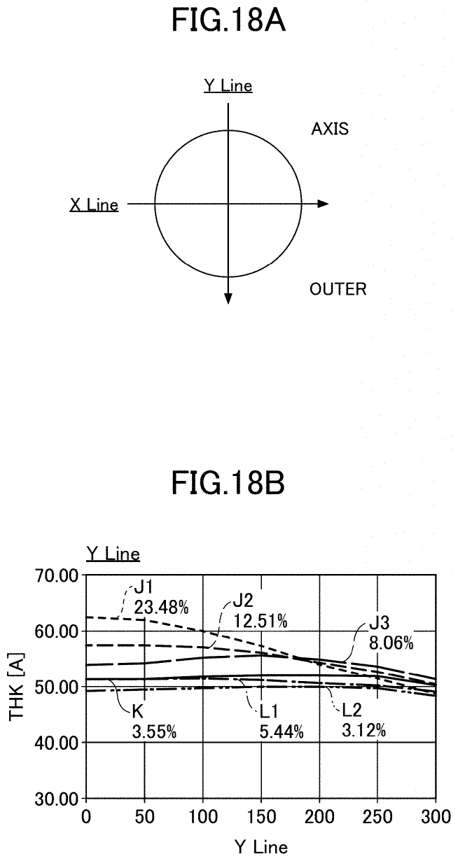

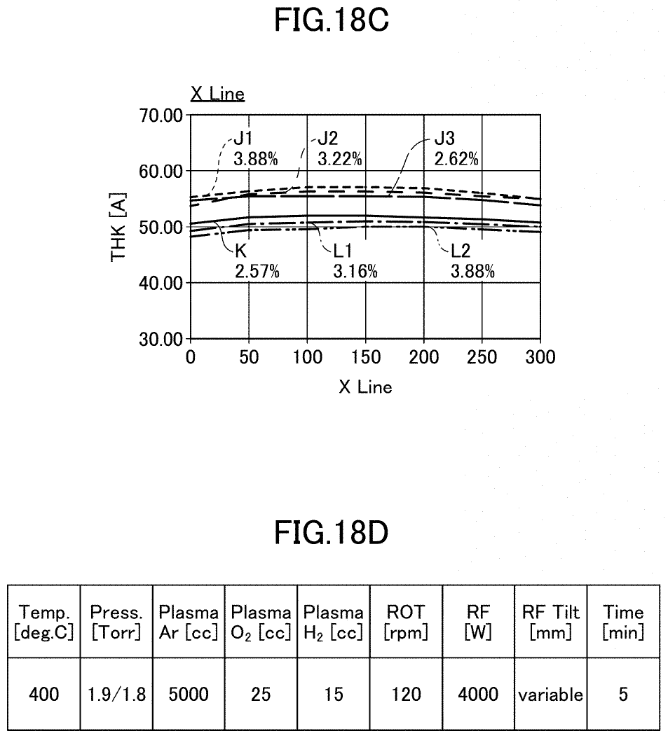

FIGS. 18A to 18D are diagrams showing a result of measuring oxidation power using antennas J1 to J3, K, L1, and L2 shown in FIG. 17.

FIG. 18A is a diagram showing coordinates within a wafer W. As shown in FIG. 18A, the coordinates of X in the circumferential direction and Y in the radial direction of the susceptor 2 were set. In the circumferential direction X, the coordinate increases from the left side to the right side, and in the radial direction Y, the coordinate increases from the central axis side to the outer peripheral side.

The oxidizing power was measured by depositing a silicon oxide film and measuring the thickness of the film. The higher the oxidation power, the thicker the film.

As the deposition conditions, as shown in FIG. 18D, the substrate temperature was set to 400° C. and the pressure in the vacuum chamber 1 was set to 1.9/1.8 Torr. The flow rate of the plasma gas was set to be 5000 sccm for Ar, 25 sccm for O₂, and 15 sccm for H₂. The rotational speed of the susceptor 2 was set to 120 rpm and the output of the radio frequency power source 85 for the plasma was set to 4000 W. The tilt width of the antenna 83 was variable, and the deposition time was set to 5 minutes.

FIG. 18B is a diagram showing a thickness of a silicon oxide film in the Y direction. As shown in FIG. 18B, in the flat shaped antennas J1 to J3, the silicon oxide film is thickly deposited on the central axis side of the Y-coordinate, and is thinly deposited on the outer peripheral side, which was not obtain the uniformity of the film thickness across the surface of the wafer W. It is understood that the antenna J3 achieves a relatively good uniformity of the film thickness among the antennas J1 to J3. In other words, although the film thickness in the center is slightly higher, the film thickness in the center and the outer periphery is substantially uniform. In contrast, the antennas J1 and J2 exhibit a large difference in thickness between the center and the outer periphery.

In contrast, in antennas K, L1, and L2, the thickness on the central axis side and the outer periphery side are almost the same, while indicating that the uniformity in film thickness is greatly improved.

FIG. 18C is a diagram showing the thickness of the silicon oxide in the X direction. As shown in FIG. 18C, the antennas J1 to J3 achieve a thick oxide film and good uniformity in film thickness in the X direction, but the thickness of the silicon oxide film varies in the Y direction.

In contrast, as shown in FIGS. 18B and 18C, in the antennas K, L1, and L2, the film thicknesses are constant in the X direction, and in addition to high uniformity of the film thickness across the surface of the wafer W in the X direction, values approximately equal to the film thickness in the Y direction are obtained, while indicating that the uniformity of film thickness across the surface of the wafer W is preferable in both the X and Y directions.

As described above, when the antenna shape is optimized based on the oxidation power, very preferable uniformity of the film thickness across the surface of the wafer W can be obtained even in the actual film deposition.

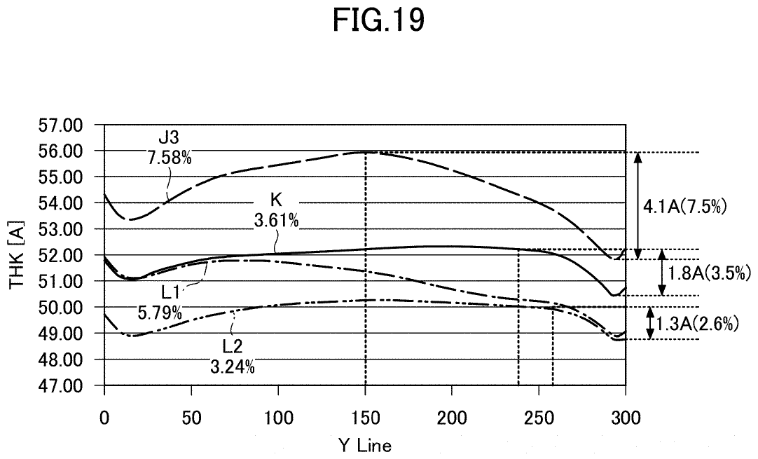

FIG. 19 is a diagram showing film thicknesses of silicon oxide films deposited using antennas J3, K, L1, and L2 in more detail. In FIG. 19, the uniformity of the film thickness across the surface of the wafer W of the antenna L1, the antenna K, and the antenna L2 is improved compared to the flat-shaped antenna J3. In the antenna J3, the variation percentage was 7.58%, but the variation percentage decreased to 5.79% for antenna L1, 3.61% for antenna K, and 3.24% for antenna L2. Thus, FIG. 19 indicates that the antenna according to the present embodiment can significantly improve the uniformity of the film deposition across the surface of the wafer W.

Incidentally, in this embodiment, the index of the oxidation power is measured by the thickness of the silicon oxide film. However, the same result can be considered to be obtained even when the comparison is made with respect to the wet etch rate or the like, as long as the amount of plasma processing is the same.

In addition, the same result can be obtained not only for the silicon oxide film but naturally also for other oxide films, for example, a metal oxide film, if the uniformity of the oxidation power of the plasma across the surface of the wafer W is improved.

Furthermore, even when a nitride film is deposited, the same concept is applied. In this case, the shape of the antenna may be optimized so as to make the nitriding power uniform, and the ideal shape T of the antenna may be calculated by calculating the point where the thickness of the film is 1 or a predetermined value with respect to the thickness of the nitride film. Furthermore, if the shape is approximated to a shape that can be actually machined, the final shape R can be determined.

In addition, as for substrate processes other than film deposition, such as etching, if the shape of the antenna can be determined based on the etching power of the antenna, the antenna and the plasma processing apparatus according to the present embodiment can be applied.

Thus, the antenna and the plasma processing apparatus according to this embodiment can be applied to various substrate processes and to the plasma generating antenna used for the substrate processes, and uniformity across a surface of a wafer can be improved in any substrate process.

As described above, according to an antenna and a plasma processing apparatus according to the embodiments, uniformity of plasma processing across a surface of a substrate can be improved.

All examples recited herein are intended for pedagogical purposes to aid the reader in understanding the disclosure and the concepts contributed by the inventor to furthering the art, and are to be construed as being without limitation to such specifically recited examples and conditions, nor does the organization of such examples in the specification relate to a showing of the superiority or inferiority of the disclosure. Although the embodiments of the present disclosure have been described in detail, it should be understood that various changes, substitutions, and alterations could be made hereto without departing from the spirit and scope of the disclosure.

What is claimed is:

1. An antenna for inductively-coupled plasma, the antenna being configured to be disposed on a process chamber, the antenna being configured to adjust an oxidizing amount or a nitriding amount of a substrate process in the process chamber by changing a shape thereof, the antenna comprising:
an antenna member disposed on the process chamber, the antenna member having a position where an oxidizing amount or a nitriding amount becomes a predetermined value at each measurement point of the antenna member, the antenna member having a shape formed based on the position of the antenna member obtained at each measurement point.

2. The antenna as claimed in claim 1, wherein the predetermined value is a normalized value with respect to a minimum value of the oxidizing amount or the nitriding amount among all measurement values.

3. The antenna as claimed in claim 1, wherein the predetermined value is a common value at each measurement point.

4. The antenna as claimed in claim 1, wherein the shape is determined by taking into consideration machinability of a metal forming the antenna member.

5. The antenna as claimed in claim 2, wherein the position of the antenna member is determined by a distance from a top face of the process chamber.

6. The antenna as claimed in claim 1,
wherein the process chamber includes a susceptor configured to receive a substrate along the susceptor in a circumferential direction, and
wherein the antenna member has a shape extending along a radial direction of the susceptor.

7. The antenna as claimed in claim 6, wherein a central side of the antenna member is disposed higher than a peripheral side of the antenna member in the radial direction of the susceptor.

8. A plasma processing apparatus, comprising:
a process chamber;
a susceptor disposed in the process chamber and configured to receive a substrate along the susceptor in a circumferential direction;
a process gas supply unit configured to supply a process gas containing at least one of an oxidizing gas and a nitriding gas to the susceptor; and
an antenna for inductively-coupled plasma disposed on the process chamber, the antenna being configured to adjust an oxidizing amount or a nitriding amount of a substrate process in the process chamber by changing a shape thereof,
wherein the antenna includes an antenna member having a position where an oxidizing amount or a nitriding amount becomes a predetermined value at each measurement point of the antenna member, the antenna member having a shape formed based on the position of the antenna member obtained at each measurement point.
